(19) United States
(12) Patent Application Publication
(10) Pub. No.: US 2003/0064324 A1
(43) Pub. Date: Apr. 3, 2003

(54) Removal of organic layers from organic electronic devices

(76) Inventors: Wei Wang, Singapore (SG); Hong Yee Low, Johor (MY); Soo Jin Chua, Singapore (SG)

Correspondence Address: TRASK BRITT, P.O. BOX 2550, SALT LAKE CITY, UT, 84110, US

(21) Appl. No.: 10/174,544

(22) Filed: Jun. 18, 2002

(30) Foreign Application Priority Data
Jun. 20, 2001 (SG) 200103758-9

(51) Int. Cl. G03F 7/00

(52) U.S. Cl. 430/313; 430/311; 430/330

(57) ABSTRACT

A method of removing organic material having a conjugated structure from a selected region of a surface of an organic microelectronic device (OMED) during production of the OMED, the method comprising the acts of providing a source of ultraviolet radiation, irradiating at least the selected region of the surface of the OMED with ultraviolet radiation, thereby photolyzing at least some of the organic material and subjecting the selected region of the surface of the OMED to a temperature sufficient to evaporate at least some of the photolysed organic material.

### BACKGROUND OF THE INVENTION

Field of the Invention: This invention relates to the removal of organic layers having a conjugated structure during the production of organic electronic devices and, in particular, to the selective removal of organic layers during the production of organic microelectronic devices (OMEDs).

State of the Art: OMEDs are typically composed of several co-planar layers, some of which are composed of organic material, upon a substrate. The manner in which an OMED functions is determined by the properties of these organic layers.

There are circumstances under which it is desirable to be able to remove selectively parts of organic layers from the surface of an underlying layer during production of an OMED. For instance, the performance of organic layers can be seriously affected by exposure to moisture or oxygen, and to stabilise the performance of OMEDs the organic layers thereof are normally hermetically sealed following fabrication of the OMED, for example by sealing the device within a cover using an adhesive such as an epoxy or acrylic based adhesive, which may be UV curable or heat curable. Prior to hermetic sealing, it is often necessary to remove the organic layers from peripheral, non-active regions of the surface of the device, thereby exposing the surface of the substrate in order to achieve a secure bond between the substrate and the covering material.

It is crucial that the organic layers are not inadvertently removed from other regions of the OMEDs, as this is likely to have an adverse affect upon the performance of the finished OMED.

Alternatively, it may be desirable to remove selectively parts of an organic layer during production of an OMED, in order to form components of prescribed shapes from the material of the organic layer. In such circumstances, the ability to remove selectively and accurately regions of organic layers is vital.

Current techniques for selective removal of organic layers during production of OMEDs comprise the mechanical abrading of the organic layers, or the dissolving thereof in solvents. However, both of these methods have proved unsatisfactory, and are prone to result in incomplete removal of the desired parts of organic layers. The technique of dissolving organic layers in solvents also suffers from the drawback that the regions of the organic layers that must be retained need to be protected from the solvents, and methods of achieving this can often be technically difficult and unreliable.

### BRIEF SUMMARY OF THE INVENTION

It is an object of the present invention to seek to provide a method of selectively removing organic layers during production of an OMED that alleviates some or all of the above drawbacks.

Accordingly, the present invention provides a method of removing organic material having a conjugated structure from a selected region of a surface of an organic microelectronic device (OMED) during production of the OMED, the method comprising the steps of: providing a source of ultraviolet radiation; irradiating at least the selected region of the surface of the OMED with ultraviolet radiation, thereby photolysing at least some of the organic material; and subjecting the selected region of the surface of the OMED to a temperature sufficient to evaporate at least some of the photolysed organic material.

Advantageously, the act of providing a source of ultraviolet light comprises the step of providing a source that is larger than the selected region of the surface of the OMED.

Preferably, the method further comprises the act of placing a mask over a further region of the surface of the substrate OMED, thereby shielding the further region of the surface of the OMED, from the ultraviolet radiation.

Conveniently, the method further comprises the act of scanning the source of ultraviolet radiation across the surface of the OMED.

Advantageously, the act of providing a source of ultraviolet radiation comprises the step of providing a source of ultraviolet radiation that is significantly smaller than the selected region of the surface of the OMED.

Preferably, the act of providing a source of ultraviolet radiation that is significantly smaller than the selected region of the surface of the OMED comprises the act of providing a source of ultraviolet radiation that produces a spot of ultraviolet light of a predetermined spot area on the surface of the OMED.

Conveniently, the act of subjecting the selected region of the surface of the OMED to a temperature sufficient to evaporate at least some of the photolysed organic material comprises the act of subjecting the selected region of the surface of the OMED to a temperature of between about 20° C. and about 150° C.

Preferably, the act of subjecting the selected region of the surface of the OMED to a temperature sufficient to evaporate at least some of the photolysed organic material comprises the act of subjecting the selected region of the surface of the OMED to a temperature in the range of from about 80° C. up to about 150° C.

Advantageously, the act of providing a source of ultraviolet radiation comprises the step of providing a source of ultraviolet radiation having a wavelength in the range of 250 nm to 400 nm.

Preferably, the method further comprises the act of treating at least the selected region of the surface of the surface of the OMED after irradiation.

Conveniently, the act of treating at least the selected region of the surface of the OMED after irradiation comprises subjecting the surface of the OMED to a vacuum, or flushing the surface of the OMED with a solvent in which at least some of the photolysed organic material is soluble.

Preferably, the organic material comprises poly (p-phenylene vinylene), poly(fluorene), polyaniline, polythiophene, 8-(hydroxyl-quinoline)aluminium, N,N′-diphenyl-N,N′-bis(3-methylphenyl)(1,1′-biphenyl)4,4′-diamine, N,N,N′,N′-tetrakis(4-methylphenyl)(1,1′-biphenyl)-4,4′-diamine or a derivative thereof.

Advantageously, the method further comprises providing a substrate, forming a layer of an organic material having a conjugated structure on a surface of the substrate and removing at least some of the organic material by any of the above methods.

Another aspect of the present invention provides a method of producing an organic microelectronic device in accordance with any of the above methods.

Preferably, the act of forming the layer of the organic material on the surface of the substrate comprises the act of thermal deposition, sputtering or solution spin-coating of the organic material onto the surface of the substrate.

Conveniently, the method further comprises the act of hermetically sealing the organic microelectronic device.

A further aspect of the present invention provides an organic microelectronic device formed by any of the above methods.

### BRIEF DESCRIPTION OF THE SEVERAL VIEWS OF THE DRAWINGS

In order that the present invention may be more readily understood, embodiments thereof will now be described, by way of example, with reference to the accompanying drawings, in which:

FIG. 1 shows a surface of an unfinished OMED prior to selective removal of an organic layer thereof;

FIG. 2 shows the selective removal of the organic layer of the OMED of FIG. 1 according to an embodiment of the present invention;

FIG. 3 shows the OMED of FIG. 1 after selective removal of the organic layer thereof; and

FIG. 4 shows the selective removal of the organic layer of the OMED of FIG. 1 according to a further embodiment of the present invention.

### DETAILED DESCRIPTION OF THE INVENTION

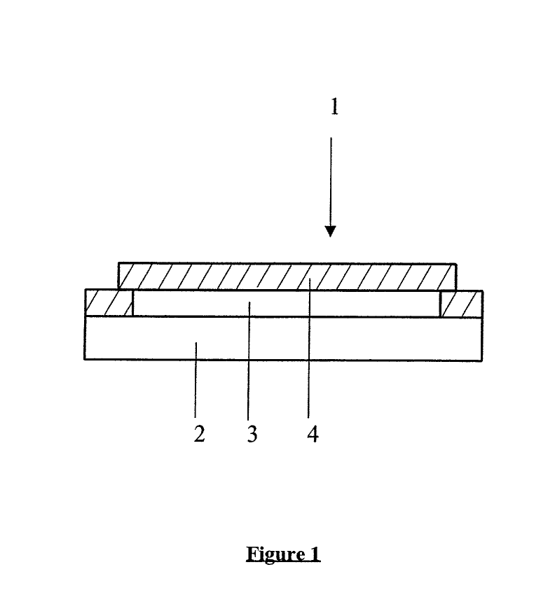

Turning first to FIG. 1, a partially-completed conventional OMED 1 comprises a substantially planar substrate 2 (which may be a glass or plastic sheet) on which a conventional thin inorganic anode layer 3 is formed. An organic microelectronic layer 4 is formed on top of and around the anode layer 3.

As described above, it is desirable to be able to remove selected regions of the organic microelectronic layer 4 from the substrate 2 or the anode layer 3. Many of the organic materials from which the organic microelectronic layer 4 is composed comprise conjugated polymers and/or molecules. A conjugated polymer or molecule, as will be understood by those of ordinary skill in the art, comprises a carbon backbone, the carbon atoms constituting the backbone being joined to one another by alternative single bonds and double or triple bonds, or by alternative phenyl rings. Such conjugated carbon-carbon bonds absorb ultraviolet light strongly.

Examples of such conjugated polymers and conjugated molecules include poly (p-phenylene vinylene), polyfluorene, polyaniline, polythiophene, and 8-(hydroxylquinoline)aluminum, N,N′-diphenyl-N,N′-bis(3-methylphenyl)(1,1′-biphenyl)4,4′-diamine, N,N,N′,N′-tetrakis(4-methylphenyl)(1,1′-biphenyl)-4,4′-diamine and derivatives thereof.

Due to this conjugated structure, the organic materials from which the organic microelectronic layer 4 is composed exhibit a very strong absorption in the ultraviolet wavelength range, and particularly in the range of wavelengths from 250-400 nm. Hence, under strong ultraviolet irradiation, the organic materials will tend to dissociate or degrade into smaller molecular fragments (a process known as photolysis). While the organic materials of which the organic microelectronic layer 4 is composed are relatively stable at ambient temperatures, the products of photolysis of the organic materials may be evaporated at such temperatures in the region of from about 20° C. to about 150° C., but more preferably from about 80° C. to about 150° C.

Hence, irradiation of a selected region of the organic microelectronic layer 4 with ultraviolet light, followed by the exposure of the partially-completed OMED 1 to at least an ambient temperature, will have the effect of removing substantially all of the organic material in the selected region, due to the photolysis of the organic material and subsequent evaporation of the products of the photolysis.

Also, it has been found that removal of the fragments of organic material may be improved by subjecting the OMED to a vacuum during or after irradiation, and also by flushing the irradiated OMED with a solvent in which the fragments are soluble.

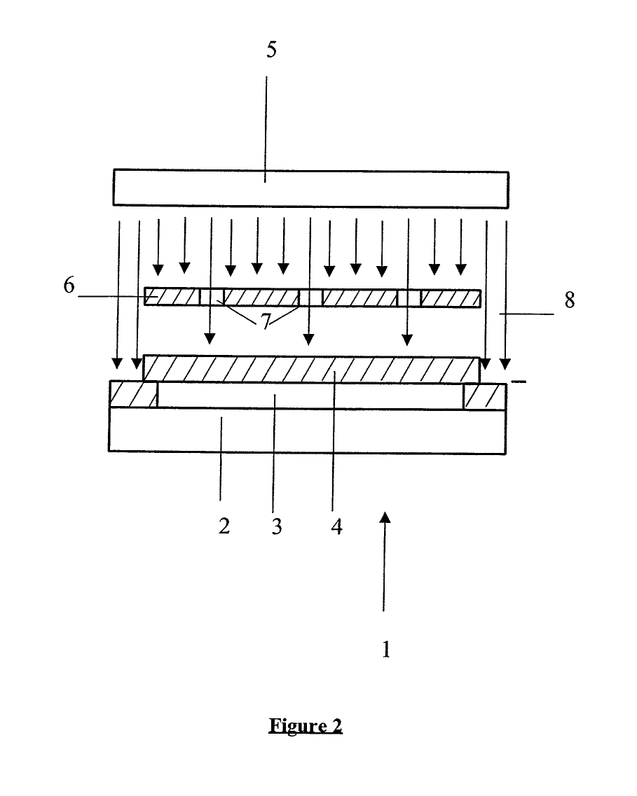

FIG. 2 shows the major components of a device for selectively removing the organic microelectronic layer 4 of the partially-completed OMED 1 in a manner embodying the present invention.

Turning to FIG. 2, a source 5 of ultraviolet light is placed opposite the partially-competed OMED 1, such that ultraviolet light is directed toward the organic microelectronic layer 4 thereof. The source 5 of ultraviolet light is of substantially the same width as the organic microelectronic layer 4 and is operable to scan across the length of the OMED 1 so as to be able to bathe the entire area of the OMED 1 in ultraviolet light. A mask 6 is interposed between the partially-completed OMED 1 and the source 5 of ultraviolet light. The mask 6 is opaque to ultraviolet light and blocks the path of ultraviolet light from the source 5 to regions of the organic microelectronic layer 4 that are not to be removed. Apertures 7 in the mask 6 allow ultraviolet light to pass from the source 5 to illuminate regions of the organic microelectronic layer 4 that it is desired to remove. Ultraviolet light from the source 5 may also be allowed to impinge on peripheral regions of the organic microelectronic layer 4 by passing around the outer edges of the mask 6. FIG. 2 shows the passage of ultraviolet light 8 from the source 5 thereof to selected regions of the organic microelectronic layer 4.

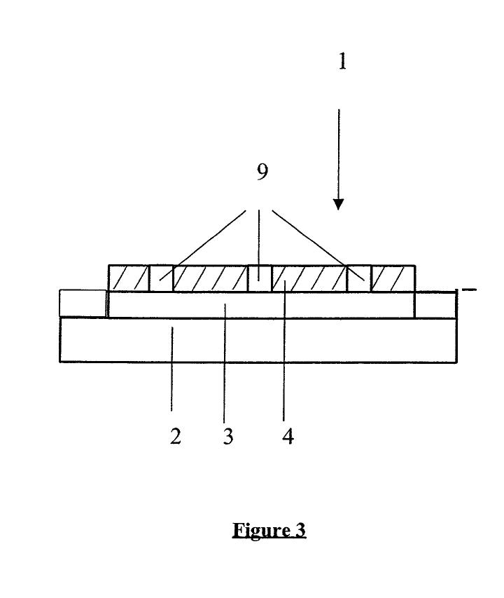

FIG. 3 shows the partially-completed OMED 1 following exposure thereof to ultraviolet light 8 from the source 5 through apertures 7 in the mask 6, and subsequent exposure of the partially-completed OMED 1 to an ambient temperature. The photolysis and subsequent evaporation of the organic material in the organic microelectronic layer 4 in the regions where ultraviolet light 8 was allowed to impinge thereon leads to gaps 9 in the organic microelectronic layer 4. It will be appreciated that the dimensions and locations of the gaps 9 in the organic microelectronic layer 4 may be easily controlled when determining the configuration of the apertures 7 in the mask 6 and the periphery of the mask 6. In particular, it will be appreciated that control over the selective removal of organic material from the organic microelectronic layer 4 may be controlled more easily than when removing the organic material therefrom by mechanical abrading or by dissolving in solvents, as described above.

As mentioned above, the mask 6 may allow ultraviolet light 8 to impinge on peripheral regions of the organic microelectronic layer 4. If this is the case, the removal of the peripheral regions of the organic microelectronic layer 4 may be exploited to allow a strong bond to form between the regions of the substrate 2 exposed thereby and covering material employed to hermetically seal the OMED 1 against exposure to moisture or oxygen.

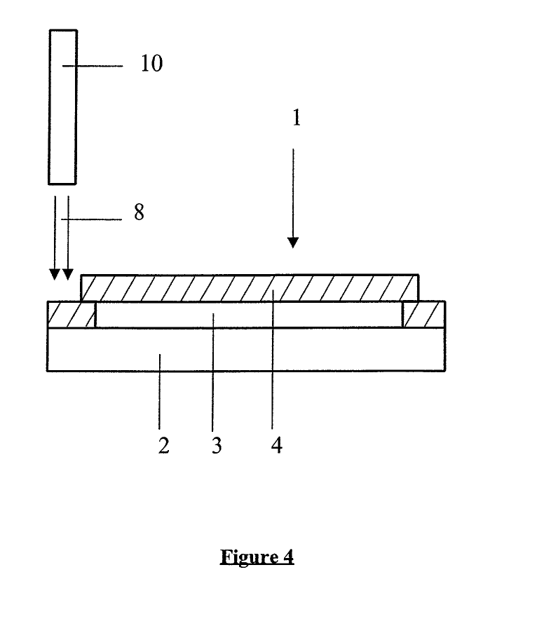

FIG. 4 shows a further method of selectively removing regions of the organic microelectronic layer 4 of a partially-completed OMED 1 embodying the present invention. In this embodiment, a relatively narrow source 10 of ultraviolet light 8 is employed, rather than using a wide source 5 of ultraviolet light 8 and a mask 6 as previously described. By irradiating small regions of the organic microelectronic layer 4 with the narrow source 10 of ultraviolet light 8, it is possible to remove selected regions of the organic microelectronic layer 4, leaving other regions thereof intact.

The narrow source 10 of ultraviolet light 8 may be scanned across the organic microelectronic layer 4, and be activated only when the narrow source 10 is directed towards the regions of the organic microelectronic layer 4 that are to be removed. In an advantageous example, the narrow source 10 of ultraviolet light 8 illuminates a preselected spot area, which is preferably of a size from about 1 μm² up to about 10,000 μm², and may be provided as part of an ultraviolet pen, which is drawn across selected regions of the organic microelectronic layer 4.

It will be appreciated that the present invention provides a simple, flexible and efficient method of selectively removing organic material during production of OMEDs. In particular, the present invention exploits the strong ultraviolet absorption of conjugated molecules and conjugated polymers to allow the simple removal of this organic material in the manufacture of OMEDs.

In the present specification “comprises” means “includes or consists of” and “comprising” means “including or consisting of”.

The features disclosed in the foregoing description, or the following claims, or the accompanying drawings, expressed in their specific forms or in terms of a means for performing the disclosed function, or a method or process for attaining the disclosed result, as appropriate, may, separately, or in any combination of such features, be utilized for realizing the invention in diverse forms thereof.

What is claimed is:

1. A method of removing organic material having a conjugated structure from a selected region of a surface of an organic microelectronic device (OMED) during production of the OMED, the method comprising:
providing a source of ultraviolet radiation;
irradiating at least the selected region of the surface of the OMED with ultraviolet radiation,
thereby photolysing at least some of the organic material; and subjecting the selected region of the surface of the OMED to a temperature sufficient to
evaporate at least some of the photolysed organic material.

2. The method according to claim 1, wherein providing a source of ultraviolet light comprises providing a source that is larger than the selected region of the surface of the OMED.

3. The method according to claim 2, further comprising placing a mask over a further region of the surface of the OMED, thereby shielding the further region of the surface of the OMED from the ultraviolet radiation.

4. The method according to claim 1, further comprising scanning the source of ultraviolet radiation across the surface of the OMED.

5. The method according to claim 1, wherein providing a source of ultraviolet radiation comprises providing a source of ultraviolet radiation that is significantly smaller than the selected region of the surface of the OMED.

6. The method according to claim 5, wherein providing a source of ultraviolet radiation that is significantly smaller than the selected region of the surface of the OMED comprises providing a source of ultraviolet radiation that produces a spot of ultraviolet light of a predetermined spot area on the surface of the OMED.

7. The method according to claim 1, wherein subjecting the selected region of the surface of the OMED to a temperature sufficient to evaporate at least some of the photolysed organic material comprises subjecting the selected region of the surface of the OMED to a temperature in the range of from about 20° C. up to about 150° C.

8. The method according to claim 7 wherein subjecting the selected region of the surface of the OMED to a temperature sufficient to evaporate at least some of the photolysed organic material comprises subjecting the selected region of the surface of the OMED to a temperature in the range of from about 80° C. up to about 150° C.

9. The method according to claim 1, wherein providing a source of ultraviolet radiation comprises providing a source of ultraviolet radiation having a wavelength in the range of 250 nm to 400 nm.

10. The method according to claim 1, further comprising treating at least the selected region of the surface of the OMED after irradiation.

11. The method according to claim 10, wherein treating the surface of the OMED after irradiation comprises subjecting the surface of the OMED to a vacuum, or flushing the surface of the OMED with a solvent in which at least some of the photolysed organic material is soluble.

12. The method according to claim 1, wherein the organic material comprises at least one of poly (p-phenylene vinylene), polyfluorene, polyaniline, polythiophene, 8-(hydroxylquinoline)aluminium, N,N′-diphenyl-N,N′-bis(3-methylphenyl)(1,1′-biphenyl)4,4′-diamine, N,N,N′,N′-tetrakis(4-methylphenyl)(1,1′-biphenyl)-4,4′-diamine or a derivative of any of the foregoing.

13. The method according to claim 1, further comprising:
providing a substrate;
forming a layer of an organic material having a conjugated structure on a surface of the substrate; and
removing at least some of the organic material.

14. The method according to claim 13, further comprising producing an organic microelectronic device using the substrate and organic material remaining thereon.

15. The method according to claim 14, further comprising hermetically sealing the organic microelectronic device.

16. The method according to claim 14, wherein forming the layer of the organic material on the surface of the substrate comprises thermal deposition, sputtering or solution spin-coating of the organic material onto the surface of the substrate.

17. The method according to claim 16, further comprising hermetically sealing the organic microelectronic device.

18. The method according to claim 13, wherein forming the layer of the organic material on the surface of the substrate comprises thermal deposition, sputtering or solution spin-coating of the organic material onto the surface of the substrate.

19. The method according claim 18, further comprising hermetically sealing the substrate and remaining microelectronic device.

20. An organic microelectronic device substantially as hereinbefore described, with reference to the accompanying drawings.
